(19) United States
(12) Patent Application Publication
(10) Pub. No.: US 2026/0344514 A1
(43) Pub. Date: Oct. 29, 2026

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Chang-Jung HSUEH, Taipei (TW); Ko-Chiao CHEN, Tainan City (TW); Tzu-Chieh WEI, Hsinchu County (TW); Yung-Hsien WANG, Hsinchu City (TW); Chien-Hsun PAN, Taichung (TW)

(21) Appl. No.: 19/192,695

(22) Filed: Apr. 29, 2025

(51) Int. Cl. H10W 90/00; H10B 80/00; H10W 70/05; H10W 70/60; H10W 70/65; H10W 72/00; H10W 74/01; H10W 74/10; H10W 74/15

(52) U.S. Cl. CPC H10W 90/00; H10W 70/05; H10W 70/611; H10W 70/65; H10W 74/016; H10W 74/121; H10W 90/401; H10W 90/701; H10B 80/00; H10W 72/0198; H10W 74/15; H10W 90/724; H10W 90/734

(57) ABSTRACT

A package structure is provided. The package structure includes a plurality of semiconductor dies over a frontside redistribution layer. The package structure includes a first molding material around the semiconductor dies. The package structure includes a backside redistribution layer below the frontside redistribution layer. The package structure includes an interconnect chip disposed between the frontside redistribution layer and the backside redistribution layer, and the interconnect chip is electrically connected to the semiconductor dies. The package structure includes a second molding material around the interconnect chip, and a sidewall of the backside redistribution layer is offset from a sidewall of the frontside redistribution layer.

### BACKGROUND

The semiconductor industry continues to improve the integration density of various electronic components (e.g., transistors, diodes, resistors, capacitors, etc.) by continual reductions in minimum feature size, which allow more components to be integrated into a given area. Individual dies are typically packaged separately. A package not only provides protection for semiconductor devices from environmental contaminants, but also provides a connection interface for the semiconductor devices packaged therein.

Three-dimensional integrated circuits (3DICs) are a recent development in semiconductor packaging in which multiple semiconductor dies are stacked upon one another, using package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, for example. However, there are many challenges related to 3DICs.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A through 1J illustrate cross-sectional views of various stages of a method for fabricating a package structure in accordance with some embodiments.

FIG. 2 illustrates an enlarged view of the region A of the package structure in FIG. 1J in accordance with some embodiments.

FIG. 3 illustrates a flowchart of the singulation process of the package structure accordance with some embodiments.

FIG. 4 illustrates an enlarged view of the region A of the package structure in accordance with some other embodiments.

FIG. 5 illustrates a flowchart of the singulation process of the package structure accordance with some other embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of package structures and method for fabricating the same are provided. The package structure includes a molding material having a stepped sidewall, and the sidewall of the backside redistribution layer is offset from the sidewall of the frontside redistribution layer. For example, the frontside redistribution layer is relatively thick (for example, including three or more layers of metallization patterns), and therefore using laser-grooving process to cut through the frontside redistribution layer may reduce the risk of damage to the frontside redistribution layer (for example, the chipping defect). As a result, the yield of the package structure can be increased.

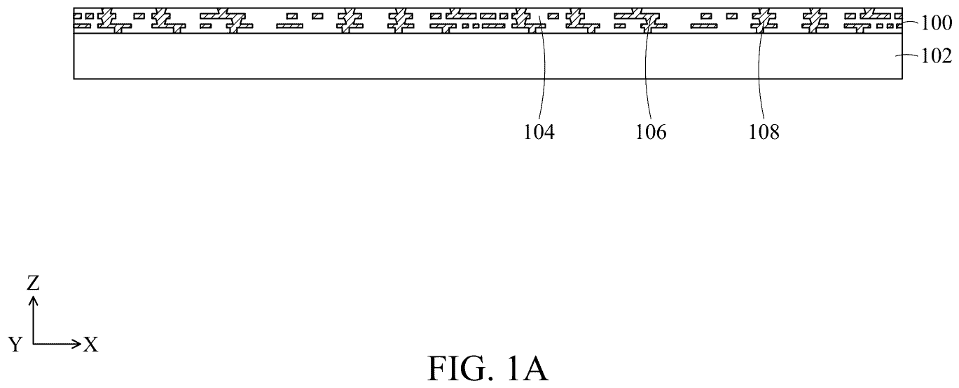

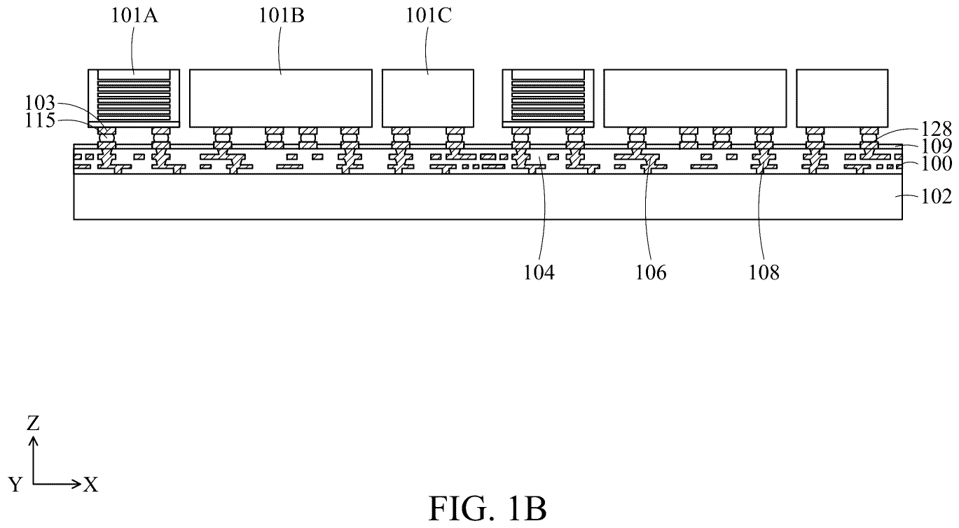

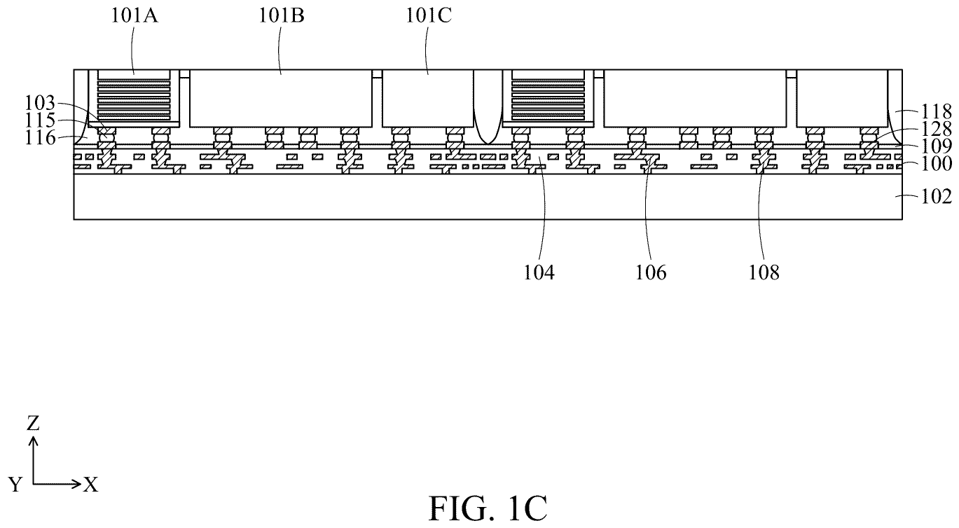

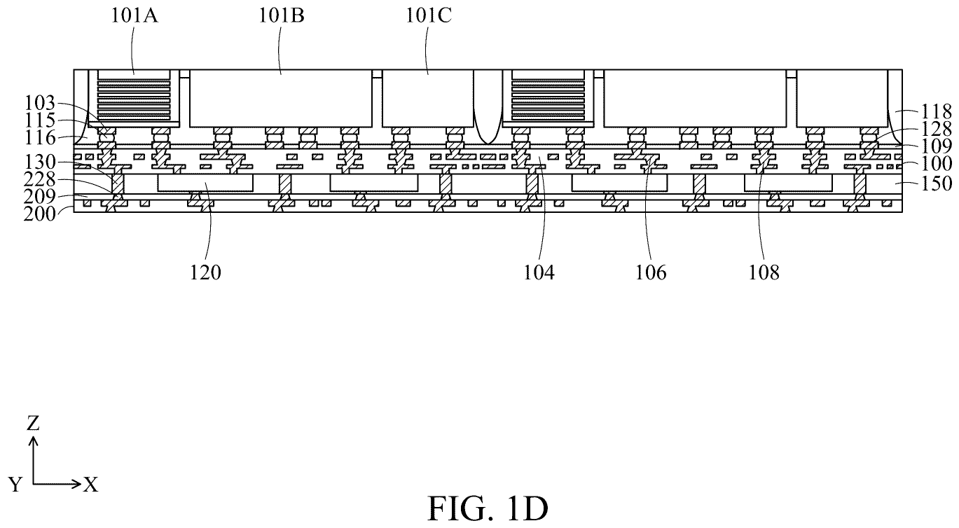

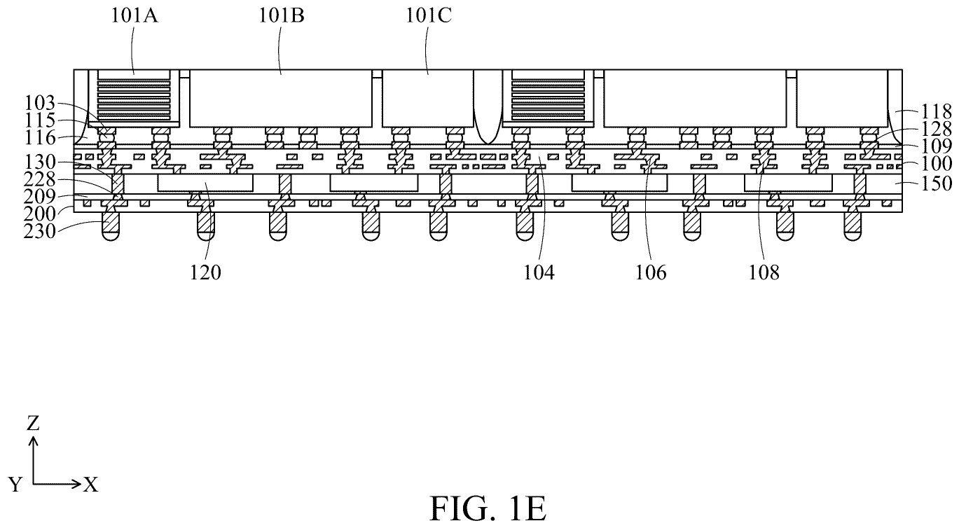

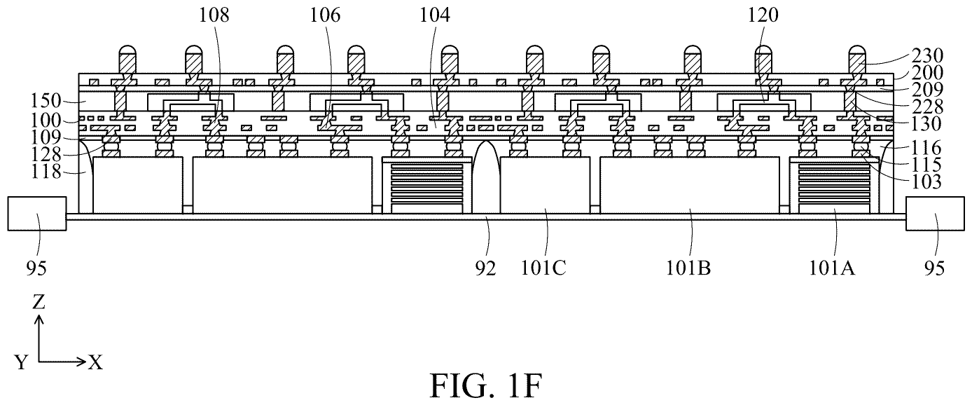

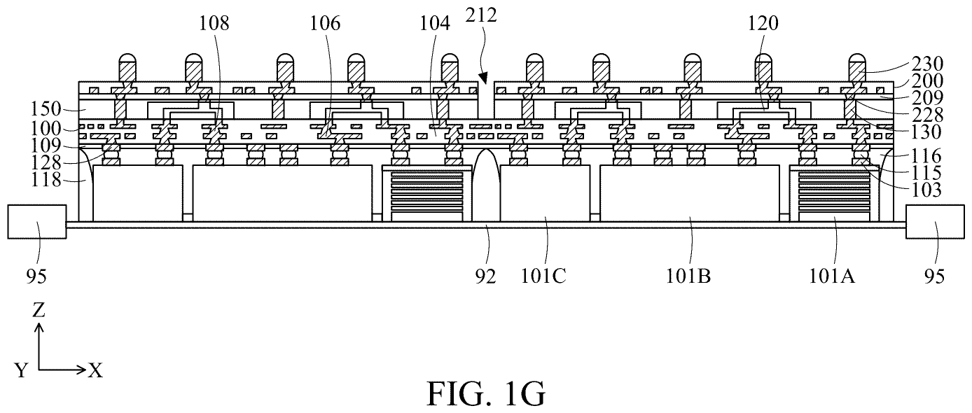

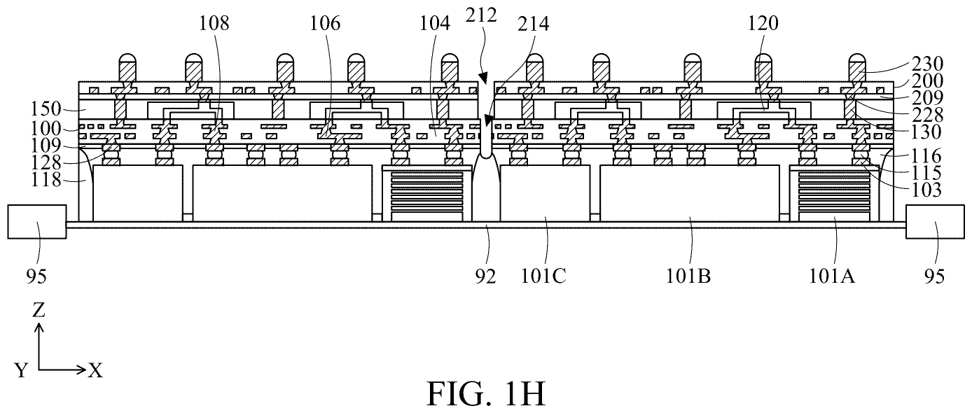

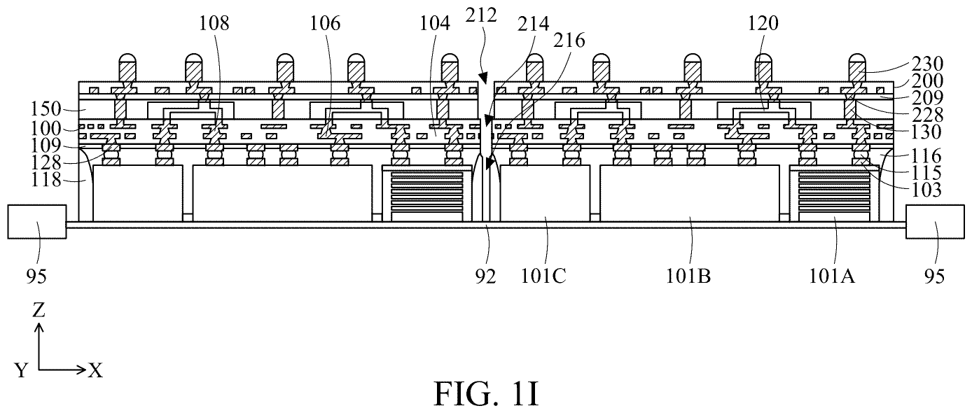

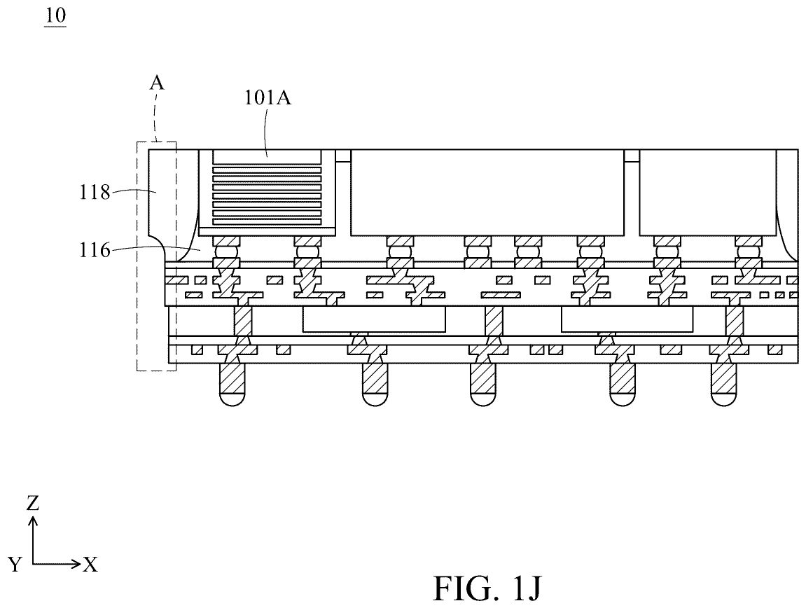

FIGS. 1A through 1J illustrate cross-sectional views of various stages of a method for fabricating the package structure 10 in accordance with some embodiments. As shown in FIG. 1A, a carrier substrate 102 is provided. The carrier substrate 102 may be a glass carrier substrate, a ceramic carrier substrate, or the like. In some embodiments, the carrier substrate 102 includes a wafer, such that multiple packages can be formed on the carrier substrate 102 simultaneously. In some embodiments, a release layer (not shown) is disposed on the carrier substrate 102 and formed of a polymer-based material, which may be removed along with the carrier substrate 102 from the overlying structures that will be formed in subsequent steps. In some embodiments, the release layer is an epoxy-based thermal-release material, which loses its adhesive property when heated, such as a light-to-heat-conversion (LTHC) release coating. In other embodiments, the release layer may be an ultra-violet (UV) glue, which loses its adhesive property when exposed to UV lights. In some embodiments, the release layer may be dispensed as a liquid and cured, may be a laminate film laminated onto the carrier substrate 102, or may be the like. In some embodiments, the top surface of the release layer is leveled and has a high degree of planarity.

In addition, a redistribution layer 100 is formed over the carrier substrate 102. The redistribution layer 100 is shown as an example having multiple layers of metallization patterns 106 and dielectric layers 104 that are alternatively stacked. In some embodiments, the dielectric layer 104 is formed of a photo-sensitive material such as PBO, polyimide, BCB, or the like, which may be patterned using a lithography mask. In some embodiments, the dielectric layers 104 are formed by spin coating, lamination, CVD, the like, or a combination thereof. In some embodiments, the dielectric layer 104 may be patterned by an acceptable process, such as by exposing and developing the dielectric layers 104 to light when the dielectric layers 104 are a photo-sensitive material or by etching using, for example, an anisotropic etch.

In some embodiments, the metallization patterns 106 include conductive elements extending along the major surface of the dielectric layers 104 and extending through the dielectric layers 104. In some embodiments, the metallization patterns may also be referred to as redistribution layers or redistribution lines. As an example to form the metallization pattern 106, a seed layer is formed over the dielectric layer 104 and in the openings extending through the dielectric layer 104. In some embodiments, the seed layer is a metal layer, which may be a single layer or a composite layer comprising a plurality of sub-layers formed of different materials. In some embodiments, the seed layer comprises a titanium layer and a copper layer over the titanium layer. In some embodiments, the seed layer is formed using, for example, physical vapor deposition (PVD) or the like. A photoresist is then formed and patterned on the seed layer. In some embodiments, the photoresist is formed by spin coating or the like and may be exposed to light for patterning. The pattern of the photoresist corresponds to the metallization pattern 106. The patterning forms openings through the photoresist to expose the seed layer. A conductive material is then formed in the openings of the photoresist and on the exposed portions of the seed layer. In some embodiments, the conductive material is formed by plating, such as electroplating or electroless plating, or the like. In some embodiments, the conductive material includes a metal, like copper, titanium, tungsten, aluminum, or the like. The combination of the conductive material and underlying portions of the seed layer form the metallization pattern 106. The photoresist and portions of the seed layer on which the conductive material is not formed are removed. In some embodiments, the photoresist is removed by an acceptable ashing or stripping process, such as using an oxygen plasma or the like. Once the photoresist is removed, exposed portions of the seed layer are removed, such as by using an acceptable etching process, such as by wet or dry etching.

In some embodiments, a plurality of via structures 108 are formed in the redistribution layer 100 and electrically coupled to the metallization pattern 106. In some embodiments, the via structures 108 have a tapered profile in the cross-sectional view. For example, the width of the via structures 108 gradually decreases towards the carrier substrate 102. However, the present disclosure is not limited thereto. In some other embodiments, the via structures 108 may have a rectangular profile in the cross-sectional view. In some embodiments, the via structures 108 are formed of tungsten (W), cobalt (Co), nickel (Ni), copper (Cu), silver (Ag), gold (Au), aluminum (Al), any other suitable conductive material, or a combination thereof. However, the present disclosure is not limited thereto.

Then, as shown in FIG. 1B, a plurality of semiconductor dies 101A, 101B, and 101C are bonded onto the redistribution layer 100 via a plurality of conductive connectors 115. For example, the semiconductor dies 101A, 101B, and 101C may include active elements or functional elements and passive elements so as to perform different functions. In some embodiments, the semiconductor dies 101A may be or include a high bandwidth memory (HBM) die, and the semiconductor dies 101B or 101C may each be or include a system-on-chip (SoC) die. However, the present disclosure is not limited thereto. For example, the semiconductor dies 101A, 101B, and 101C may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die or an application processor (AP) die, or may independently be or include a memory die such as a high bandwidth memory (HBM) die.

For example, the conductive connectors 115 may be referred to as micro bumps, but the present disclosure is not limited thereto. In some embodiments, a passivation layer 109 and a plurality of bonding features 128 are formed on the redistribution layer 100. In some embodiments, the bonding features 128 are formed in the passivation layer 109 and electrically connected to the redistribution layer 100. For example, the bonding features 128 on the redistribution layer 100 include conductive material such as tungsten (W), cobalt (Co), nickel (Ni), copper (Cu), silver (Ag), gold (Au), aluminum (Al), any other suitable conductive material, or a combination thereof. In some embodiments, the bonding features 128 on the redistribution layer 100 are formed corresponding to the semiconductor dies 101A, 101B, and 101C to be bonded. However, the present disclosure is not limited thereto.

Similarly, a plurality of bonding features 103 are formed on the semiconductor dies 101A, 101B, and 101C. For example, the bonding features 103 on the semiconductor dies 101A, 101B, and 101C include conductive material such as tungsten (W), cobalt (Co), nickel (Ni), copper (Cu), silver (Ag), gold (Au), aluminum (Al), any other suitable conductive material, or a combination thereof. In some embodiments, the bonding features 128 on the redistribution layer 100 are aligned with the bonding features 103 on the semiconductor dies 101A, 101B, and 101C to form electrical connection between the redistribution layer 100 and the semiconductor dies 101A, 101B, and 101C.

In some embodiments, the conductive connectors 115 are provided in between the bonding features, and a reflow process is performed so that the conductive connectors 115 are electrically connected to the redistribution layer 100 and the semiconductor dies 101A, 101B, and 101C. In some embodiments, the conductive connectors 115 include a conductive material such as solder, tin, or the like. For example, the conductive connectors 115 are formed by initially forming a layer of solder through evaporation, electroplating, printing, solder transfer, ball placement, or the like. Thereafter, the reflow process may be performed in order to shape the solder material, so that the conductive connectors 115 are joined with the redistribution layer 100 and the semiconductor dies 101A, 101B, and 101C. However, the present disclosure is not limited thereto.

Then, as shown in FIG. 1C, an underfill 116 is formed over the redistribution layer 100 (e.g., over the passivation layer 109). In some embodiments, the underfill 116 is located around the conductive connectors 115. In some embodiments, the underfill 116 is formed by a capillary flow process after the semiconductor dies 101A, 101B, and 101C are attached or is formed by a suitable deposition method before the semiconductor dies 101A, 101B, and 101C are attached. In some embodiments, the underfill 116 is also between the semiconductor dies 101A, 101B, and 101C.

In some embodiments, a molding material 118 is supplied over the redistribution layer 100 and covers the semiconductor dies 101A, 101B, and 101C and the underfill 116. After formation, the molding material 118 encapsulates the semiconductor dies 101A, 101B, and 101C and the conductive connectors 115 over the redistribution layer 100. In some embodiments, the molding material 118 may include epoxy molding compound (EMC). For example, the molding material 118 includes polymethyl methacrylate (PMMA), acrylonitrile butadiene styrene (ABS), polyamide (PA), polycarbonate (PC), polyethylene (PE), polyoxymethylene (POM), polypropylene (PP), polystyrene (PS), thermoplastic elastomer (TPE), thermoplastic polyurethane (TPU), etc.), epoxy, or the like. In some embodiments, the molding material 118 is supplied by compression molding, transfer molding, or the like. In some embodiments, the molding material 118 is supplied in liquid or semi-liquid form and then subsequently cured, which increases the mobility of the molding material 118 and therefore being able to fill in the gap (if present) between the semiconductor dies 101A, 101B, and 101C with relatively high aspect ratio. In some embodiments, a planarization process (such as, chemical mechanical polish (CMP), molding compound grinding (MCG) or any other suitable planarization process) may be performed to remove and planarize the upper surface of the molding material 118. As a result, the top surface of the molding material 118, and the top surfaces of the semiconductor dies 101A, 101B, and 101C are substantially coplanar (within process variation).

Then, as shown in FIG. 1D, the carrier substrate 102 is detached (or “de-bonded”) from the redistribution layer 100. In accordance with some embodiments, the removal of the carrier substrate 102 includes projecting a light such as a laser light or an UV light on the release layer so that the release layer decomposes under the heat of the light and the carrier substrate 102 can be removed. However, the present disclosure is not limited thereto.

Next, as shown in FIG. 1D, a plurality of conductive connectors 130 are formed over the redistribution layer 100. For example, the conductive connectors 130 may include through vias for connecting the redistribution layer 100 and the redistribution layer 200 (which will be discussed in detail below). However, the present disclosure is not limited thereto. In some embodiments, interconnect chip 120 is bonded to and electrically connected to the redistribution layer 100. In some embodiments, the interconnect chip 120 overlaps at least one of the semiconductor dies 101A, 101B, and 101C in the normal direction (for example, parallel to the Z direction) of the redistribution layer 100. The interconnect chip 120 may be configured to transmit signals between the semiconductor dies 101A, 101B, and 101C, and therefore enhancing the performance of the package structure.

Then, as shown in FIG. 1D, a redistribution layer 200 is bonded to the redistribution layer 100 via the conductive connectors 130. In some embodiments, a passivation layer 209 is formed over the redistribution layer 200, and a plurality of conductive features 228 are formed in the passivation layer 209 and aligned with the conductive connectors 130. In some embodiments, some conductive features 228 may also be connected with the interconnect chip 120. Next, a molding material 150 is disposed between the redistribution layer 200 and the redistribution layer 100, and encapsulates the interconnect chip 120 and the conductive connectors 130. In some embodiments, the molding material 150 is formed by a capillary flow process after the redistribution layer 200 is bonded to the redistribution layer 100. It should be noted that the redistribution layer 100 may be referred to as “the frontside redistribution layer 100,” and the redistribution layer 200 may be referred to as “the backside redistribution layer 200.” These terms are provided for distinguishing the redistribution layers 100 and 200, but not intended to imply the orientation of the package structure 10.

Then, as shown in FIG. 1E, a plurality of conductive connectors 230 are formed on the redistribution layer 200. For example, the conductive connectors 230 may include ball grid array (BGA) bumps, but the present disclosure is not limited thereto. In some embodiments, the conductive connectors 230 may include controlled collapse chip connection (C4) bumps, solder bumps, copper bumps, micro bumps, electroless nickel-electroless palladium-immersion gold technique (ENEPIG) formed bumps, copper pillars, or the like. However, the present disclosure is not limited thereto.

Next, as shown in FIG. 1F, the overall structure is flipped and placed on the tape 92, which is held by the frame 95, for the subsequent singulation process. As shown in FIG. 1G, the singulation process is performed by initially forming a first recess 212 along the scribe line (that is, between the package structure 10 to be formed). For example, the first recess 212 is formed by a first sawing process using a first laser recipe. The first recess 212 cuts through the backside redistribution layer 200 and extends into the molding material 150. In some embodiments, the first recess 212 does not completely cut through the molding material 150. That is, after the first recess 212 is formed, the frontside redistribution layer 100 is still covered by the molding material 150.

Then, as shown in FIG. 1H, the singulation process is further performed by forming a second recess 214 along the scribe line (that is, between the package structure 10 to be formed) and below the first recess 212. For example, the second recess 214 is formed by a laser-grooving process using a second laser recipe. It should be noted that the first laser recipe is different from the second laser recipe. For example, the first sawing process is performed using nanosecond laser, and the laser-grooving process is performed using picosecond laser. In some embodiments, the etch rate of the first sawing process is faster than the etch rate of the laser-grooving process. In some embodiments, the power of the first sawing process is greater than the power of the laser-grooving process. It should be noted that the frontside redistribution layer 100 is relatively thick (for example, including three or more layers of metallization patterns), and therefore using laser-grooving process to cut through the frontside redistribution layer 100 may reduce the risk of damage to the frontside redistribution layer 100 (for example, the chipping defect). As a result, the yield of the package structure can be increased.

In some embodiments, the second recess 214 cuts through the molding material 150 and the frontside redistribution layer 100 and extends into the molding material 118. In some embodiments, the second recess 214 does not completely cut through the molding material 118. That is, after the second recess 214 is formed, the molding material 118 is partially etched, and the tape 92 is not exposed from the molding material 118.

Next, as shown in FIG. 1I, the singulation process is further performed by forming a third recess 216 along the scribe line (that is, between the package structure 10 to be formed) and below the second recess 214. For example, the third recess 216 is formed by a second sawing process using the first laser recipe. The third recess 216 cuts through the molding material 118 and separates different package structures. In some embodiments, the second sawing process is performed using nanosecond laser. In some other embodiments, the second sawing process is performed using another laser recipe different than the first laser recipe. As shown in FIG. 1J, the singulated package structure is taken from the tape, and an exemplary package structure 10 is formed. For example, the package structure 10 includes or is a package including a chip-on-wafer-on-substrate (CoWoS) package. However, the present disclosure is not limited thereto. In some embodiments, the package structure 10 includes or is a package including a multi-chip stacked package, a chip on wafer (CoW) package, an integrated fan-out (InFO) package, a three-dimensional integrated circuit (3DIC) package, or a combination thereof. In some embodiments, the package structure 10 includes an InFO package.

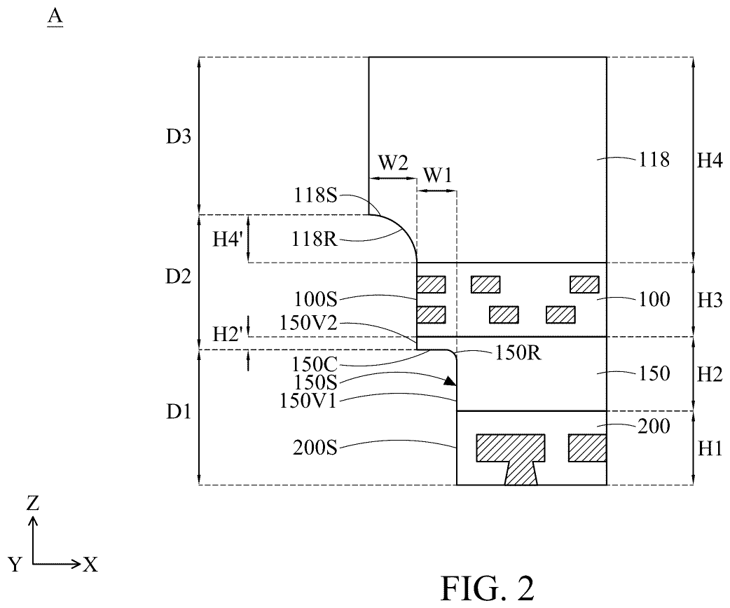

FIG. 2 illustrates an enlarged view of the (edge) region A of the package structure in FIG. 1J in accordance with some embodiments. As shown in FIG. 2, the thickness H1 of the backside redistribution layer 200 is less than the thickness H3 (for example, about 10μm) of the frontside redistribution layer 100. As a result, using the high-power first sawing process is less likely to damage the backside redistribution layer 200 (for example, the chipping defect). The depth D1 of the first recess 212 (referring to FIG. 1G, for example) is greater than the thickness H1 of the backside redistribution layer 200, and less than the sum of the thickness H2 of the molding material 150 and the thickness H1 of the backside redistribution layer 200. That is, the backside redistribution layer 200 is completely cut through by the first sawing process, and a portion of the molding material 150 remains after the first sawing process. As a result, the molding material 150 includes a stepped sidewall 150S. For example, the stepped sidewall 150S includes a first vertical section 150V1 that is aligned with the sidewall 200S of the backside redistribution layer 200. The stepped sidewall 150S also includes a second vertical section 150V2 that is aligned with the sidewall 100S of the frontside redistribution layer 100. The stepped sidewall 150S further includes a connecting section 150C that is connected to the first vertical section 150V1 and the second vertical section 150V2.

In some embodiments, the first vertical section 150V1 is longer than the second vertical section 150V2. In some embodiments, the ratio of the length H2′ of the second vertical section 150V2 to the thickness H2 of the molding material 150 is from about 10% to about 50%. Accordingly, the first sawing process can etch most of the molding material 150 rapidly, thereby reducing the amount of time needed for the singulation process. Also, the risk that the frontside redistribution layer 100 is cut by the high-power first sawing process can be reduced, and therefore chipping defects are less likely to occur on the sidewall 100S of the frontside redistribution layer 100. Due to the first sawing process, a rounded corner 150R is formed between the connecting section 150C and the first vertical section 150V1. In some embodiments, the width W1 of the connecting section 150C is less than the depth D1 of the first recess 212.

In some embodiments, the depth D2 of the second recess 214 (referring to FIG. 1H, for example) is greater than the thickness H3 of the frontside redistribution layer 100. That is, the frontside redistribution layer 100 is completely cut through by the laser-grooving process, and a portion of the molding material 118 remains after the laser-grooving process. For example, the laser-grooving process cuts through the molding material 150 and the frontside redistribution layer 100, and forms a stepped sidewall 118S in the molding material 118. In some embodiments, the ratio of the depth D2 of the second recess 214 to the thickness H3 of the frontside redistribution layer 100 is from about 1.05 to about 1.15. In this way, it can be ensured that the frontside redistribution layer 100 is completely cut through by the low-power laser-grooving process, reducing the risk of causing a chipping defect on the sidewall 100S of the frontside redistribution layer 100. Also, the process time of the singulation process may not be too long to cause additional cost. It should be noted that since the backside redistribution layer 200 and the frontside redistribution layer 100 are cut using different processes, the sidewall 200S of the backside redistribution layer 200 is offset from the sidewall 100S of the frontside redistribution layer 100. That is, a portion of the frontside redistribution layer 100 extends beyond the backside redistribution layer 200 when viewed in the cross-sectional view, and the portion of the frontside redistribution layer 100 does not overlap the backside redistribution layer 200 in the normal direction (for example, the Z direction) of the frontside redistribution layer 100.

In some embodiments, due to the laser-grooving process, a rounded corner 118R is formed on the stepped sidewall 118S. Because of the different laser recipes of the first sawing process and the laser-grooving process, the radius of the rounded corner 118R in the molding material 118 is different from the radius of the rounded corner 150R in the molding material 150. That is to say, in the cross-sectional view, the profile of the stepped sidewall 118S is different from the profile of the stepped sidewall 150S. For example, the radius of the rounded corner 118R in the molding material 118 is greater than the radius of the rounded corner 150R in the molding material 150 since the power of the first sawing process is greater than the power of the laser-grooving process.

In some embodiments, the depth D3 of the third recess 216 (referring to FIG. 1I, for example) is less than the thickness H4 of the molding material 118 since the molding material 118 has been partially etch by the previous laser-grooving process. For example, the molding material 118 is completely cut through by the high-power second sawing process. In this way, it helps to reduce the process time of the singulation process and save the process cost.

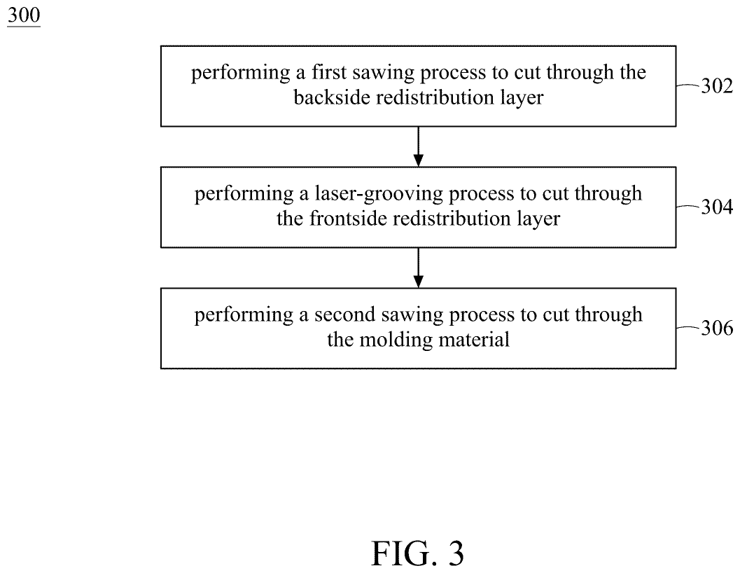

FIG. 3 illustrates a flowchart of the singulation process of the package structure in accordance with some embodiments. As shown in FIG. 3, the method 300 includes step 302, in which a first sawing process is performed to cut through the backside redistribution layer 200. In addition, the method 300 includes step 304, in which a laser-grooving process is performed to cut through the frontside redistribution layer 100. Furthermore, the method 300 includes step 306, in which a second sawing process is performed to cut through the molding material 118. As set forth above, the singulation process may include alternative sawing process and laser-grooving process for cutting different portions of the package structure. In this way, the yield and process time of the package structure may strike a balance for improving the manufacturing of the package structure.

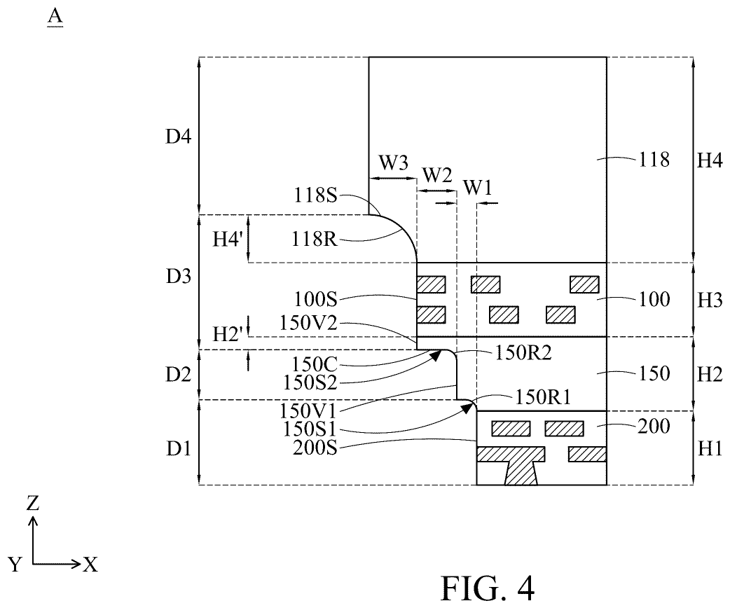

FIG. 4 illustrates an enlarged view of the region A of the package structure in accordance with some other embodiments. It should be noted that the package structure in the present embodiment may include elements or portions that are the same as or similar to those of the package structure shown in FIG. 2. For the sake of brevity, these elements or portions are denoted by the same or similar reference numerals, and will not be discussed in detail below. As shown in FIG. 4, the molding material 150 is formed between the frontside redistribution layer 100 and the backside redistribution layer 200, and the molding material 118 is located over the frontside redistribution layer 100. The difference between the package structure in the present embodiment and the package structure shown in FIG. 2 is that the backside redistribution layer 200 is also relatively thick (for example, including three or more layers of metallization patterns), and therefore it is required to use laser-grooving process to cut through the backside redistribution layer 200, so as to reduce the risk of damage to the backside redistribution layer 200 (for example, the chipping defect).

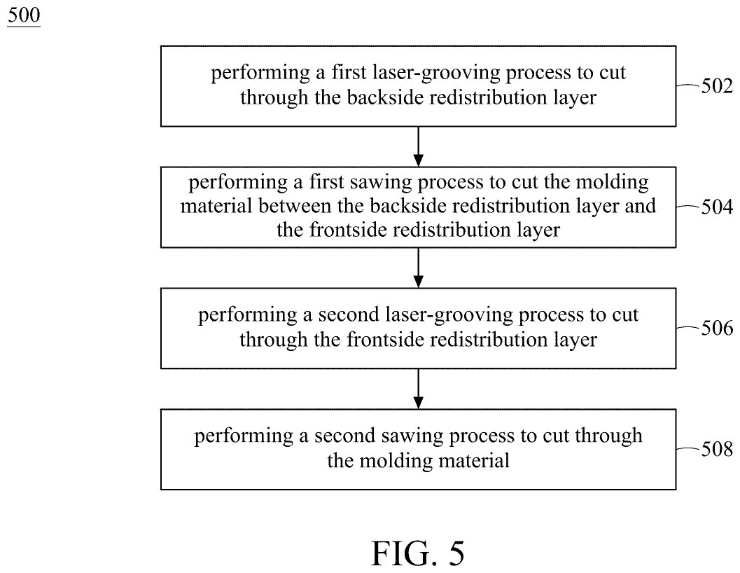

In some embodiments, the depth D1 of the recess formed by the first laser-grooving process (referring to step 502 shown in FIG. 5, for example) is greater than the thickness H1 of the backside redistribution layer 200, and less than the sum of the thickness H2 of the molding material 150 and the thickness H1 of the backside redistribution layer 200. That is, the backside redistribution layer 200 is completely cut through by the first laser-grooving process, and a major portion of the molding material 150 remains after the first laser-grooving process. As a result, the molding material 150 includes a first stepped sidewall 150S1. For example, the first stepped sidewall 150S1 is connected to and aligned with the sidewall 200S of the backside redistribution layer 200. In some embodiments, the width W1 of the first stepped sidewall 150S1 is less than the depth D1 of the recess formed by the first laser-grooving process. Similarly, due to the first laser-grooving process, a rounded corner 150R1 is formed on the first stepped sidewall 150S1.

In some embodiments, the depth D2 of the recess formed by the first sawing process (referring to step 504 shown in FIG. 5, for example) is less than the thickness H2 of the molding material 150 since the molding material 150 has been partially etch by the previous laser-grooving process. As a result, the molding material 150 includes a second stepped sidewall 150S2. For example, the second stepped sidewall 150S2 is connected to and aligned with the sidewall 100S of the frontside redistribution layer 100. In some embodiments, the width W2 of the second stepped sidewall 150S2 is less than the depth D2 of the recess formed by the first sawing process. Similarly, due to the first sawing process, a rounded corner 150R2 is formed on the second stepped sidewall 150S2. Because of the different laser recipes of the first sawing process and the first laser-grooving process, the radius of the rounded corner 150R2 on the second stepped sidewall 150S2 is different from the radius of the rounded corner 150R1 on the first stepped sidewall 150S1. That is to say, in the cross-sectional view, the profile of the first stepped sidewall 150S1 is different from the profile of the second stepped sidewall 150S2. For example, the radius of the rounded corner 150R2 on the second stepped sidewall 150S2 is less than the radius of the rounded corner 150R1 on the first stepped sidewall 150S1. As set forth above, the first sawing process can etch most of the molding material 150 rapidly, thereby reducing the amount of time needed for the singulation process. Also, the risk of cutting the frontside redistribution layer 100 in the high-power first sawing process can be reduced, and therefore chipping is less likely to occur on the sidewall 100S of the frontside redistribution layer 100.

In some embodiments, the depth D3 of the recess formed by the second laser-grooving process (referring to step 506 shown in FIG. 5, for example) is greater than the thickness H3 of the frontside redistribution layer 100. That is, the frontside redistribution layer 100 is completely cut through by the second laser-grooving process, and a portion of the molding material 118 remains after the laser-grooving process. For example, the second laser-grooving process cuts through the molding material 150 and the frontside redistribution layer 100, and partially etches the molding material 118. In this way, it can be ensured that the frontside redistribution layer 100 is completely cut through by the low-power laser-grooving process, reducing the risk of chipping the sidewall 100S of the frontside redistribution layer 100. Also, the process time of the singulation process may not be too long to cause additional cost.

In some embodiments, the depth D4 of the recess formed by the first sawing process (referring to step 504 shown in FIG. 5, for example) is less than the thickness H4 of the molding material 118 since the molding material 118 has been partially etch by the previous laser-grooving process. For example, the molding material 118 is completely cut through by the high-power second sawing process. In this way, it helps to reduce the process time of the singulation process and save the process cost. In some embodiments, the width W3 of the sidewall of the molding material 118 is less than the depth D4 of the recess formed by the second sawing process.

FIG. 5 illustrates a flowchart of the singulation process of the package structure in accordance with some other embodiments. As shown in FIG. 5, the method 500 includes step 502, in which a first laser-grooving process is performed to cut through the backside redistribution layer 200. Then, the method 500 includes step 504, in which a first sawing process is performed to cut the molding material 150 between the backside redistribution layer 200 and the frontside redistribution layer 100. In addition, the method 500 includes step 506, in which a second laser-grooving process is performed to cut through the frontside redistribution layer 100. Furthermore, the method 500 includes step 508, in which a second sawing process is performed to cut through the molding material 118. As set forth above, the singulation process may include alternative sawing process and laser-grooving process for cutting different portions of the package structure. In this way, the yield and process time of the package structure may strike a balance for improving the manufacturing of the package structure.

Embodiments of package structures and method for fabricating the same are provided. The package structure includes a molding material having a stepped sidewall, and the sidewall of the backside redistribution layer is offset from the sidewall of the frontside redistribution layer. For example, the frontside redistribution layer is relatively thick (for example, including three or more layers of metallization patterns), and therefore using laser-grooving process to cut through the frontside redistribution layer may reduce the risk of damage to the frontside redistribution layer (for example, the chipping defect). As a result, the yield of the package structure can be increased. In addition, the singulation process may include alternative sawing process and laser-grooving process for cutting different portions of the package structure. In this way, the yield and process time of the package structure may strike a balance for improving the manufacturing of the package structure.

In some embodiments, a package structure is provided. The package structure includes a plurality of semiconductor dies over a frontside redistribution layer. The package structure includes a first molding material around the semiconductor dies. The package structure includes a backside redistribution layer below the frontside redistribution layer. The package structure includes an interconnect chip disposed between the frontside redistribution layer and the backside redistribution layer, and the interconnect chip is electrically connected to the semiconductor dies. The package structure includes a second molding material around the interconnect chip, and a sidewall of the backside redistribution layer is offset from a sidewall of the frontside redistribution layer.

In some embodiments, a package structure is provided. The package structure includes a plurality of semiconductor dies over a frontside redistribution layer. The package structure includes a first molding material around the semiconductor dies, and the first molding material includes a first stepped sidewall. The package structure includes a backside redistribution layer below the frontside redistribution layer. The package structure includes a plurality of conductive connectors disposed between the frontside redistribution layer and the backside redistribution layer, and the interconnect chip is electrically connected to the semiconductor dies. The package structure also includes a second molding material around the conductive connectors, and the second molding material includes a second stepped sidewall. In the cross-sectional view, the profile of the first stepped sidewall is different from the profile of the second stepped sidewall.

In some embodiments, a method for fabricating a package structure is provided. The method includes bonding a plurality of semiconductor dies over a first surface of a frontside redistribution layer. The method includes forming a molding layer over a second surface of the frontside redistribution layer, wherein the molding layer surrounds a plurality of through vias. The method includes forming a backside redistribution layer over the molding layer, wherein the backside redistribution layer is electrically connected to the frontside redistribution layer through the through vias. The method also includes performing a singulation process, which includes performing a first sawing process using a first laser recipe, wherein the first sawing process forms a first recess in the backside redistribution layer and the molding layer; and performing a laser-grooving process using a second laser recipe after performing the first sawing process, wherein the first laser recipe is different from the second laser recipe, the laser-grooving process forms a second recess in the molding layer and the frontside redistribution layer, and the second recess is below the first recess.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a plurality of semiconductor dies over a frontside redistribution layer;
a first molding material around the semiconductor dies;
a backside redistribution layer below the frontside redistribution layer, wherein a sidewall of the backside redistribution layer is offset from a sidewall of the frontside redistribution layer;
an interconnect chip disposed between the frontside redistribution layer and the backside redistribution layer, wherein the interconnect chip is electrically connected to the semiconductor dies; and
a second molding material around the interconnect chip.

2. The package structure as claimed in claim 1, wherein a sidewall of the second molding material comprises:
a first vertical section aligned with the sidewall of the backside redistribution layer; and
a second vertical section aligned with the sidewall of the frontside redistribution layer, wherein the first vertical section is longer than the second vertical section.

3. The package structure as claimed in claim 2, wherein the sidewall of the second molding material further comprises a connecting section connected to the first vertical section and the second vertical section, and a rounded corner is formed between the connecting section and the first vertical section.

4. The package structure as claimed in claim 3, wherein a first molding material comprises a rounded corner, and a radius of the rounded corner in the first molding material is different from a radius of the rounded corner in the second molding material.

5. The package structure as claimed in claim 1, wherein a thickness of the frontside redistribution layer is greater than a thickness of the backside redistribution layer.

6. The package structure as claimed in claim 1, further comprising a plurality of conductive connectors disposed on the backside redistribution layer, and in a direction perpendicular to the sidewall of the backside redistribution layer, the sidewall of the backside redistribution layer is closer to the conductive connectors than the sidewall of the frontside redistribution layer.

7. A package structure, comprising:
a plurality of semiconductor dies over a frontside redistribution layer;
a first molding material around the semiconductor dies, wherein the first molding material comprises a first stepped sidewall;
a backside redistribution layer below the frontside redistribution layer;
a plurality of conductive connectors disposed between the frontside redistribution layer and the backside redistribution layer; and
a second molding material around the conductive connectors, wherein the second molding material comprises a second stepped sidewall, wherein in a cross-sectional view, a profile of the first stepped sidewall is different from a profile of the second stepped sidewall.

8. The package structure as claimed in claim 7, wherein the first stepped sidewall comprises a first rounded corner, the second stepped sidewall comprises a second rounded corner, and a radius of the first rounded corner is greater than a radius of the second rounded corner.

9. The package structure as claimed in claim 7, wherein the second molding material further comprises a third stepped sidewall connected to the second stepped sidewall via a vertical section.

10. The package structure as claimed in claim 9, wherein in the cross-sectional view, a profile of the third stepped sidewall is different from the profile of the second stepped sidewall.

11. The package structure as claimed in claim 7, wherein the frontside redistribution layer comprises at least three sub-layers of conductive material.

12. The package structure as claimed in claim 7, wherein a portion of the frontside redistribution layer extends beyond the backside redistribution layer when viewed in the cross-sectional view.

13. A method for fabricating a package structure, comprising:
bonding a plurality of semiconductor dies over a first surface of a frontside redistribution layer;
forming a molding layer over a second surface of the frontside redistribution layer, wherein the molding layer surrounds a plurality of through vias;
forming a backside redistribution layer over the molding layer, wherein the backside redistribution layer is electrically connected to the frontside redistribution layer through the through vias; and
performing a singulation process, comprising:
performing a first sawing process using a first laser recipe, wherein the first sawing process forms a first recess in the backside redistribution layer and the molding layer; and
performing a laser-grooving process using a second laser recipe after performing the first sawing process, wherein the first laser recipe is different from the second laser recipe, the laser-grooving process forms a second recess in the molding layer and the frontside redistribution layer, and the second recess is below the first recess.

14. The method as claimed in claim 13, wherein the first sawing process cuts through the backside redistribution layer, and the laser-grooving process cuts through the frontside redistribution layer.

15. The method as claimed in claim 13, wherein performing the singulation process further comprises:
performing a second sawing process using the first recipe after performing the laser-grooving sawing process, wherein the singulation process is completed once the second sawing process ends.

16. The method as claimed in claim 13, wherein an etch rate of the first sawing process is faster than an etch rate of the laser-grooving process.

17. The method as claimed in claim 13, wherein a power of the first sawing process is greater than a power of the laser-grooving process.

18. The method as claimed in claim 13, wherein a width of the first recess is greater than a width of the second recess.

19. The method as claimed in claim 18, wherein a depth of the second recess is greater than a thickness of the frontside redistribution layer.

20. The method as claimed in claim 19, wherein a ratio of the depth of the second recess to the thickness of the frontside redistribution layer is from about 1.05 to about 1.15.
